(19) United States
(12) Patent Application Publication
(10) Pub. No.: US 2023/0288476 A1
(43) Pub. Date: Sep. 14, 2023

(54) METHOD AND APPARATUS OF ANALYZING DATA, AND STORAGE MEDIUM

(71) Applicant: CHANGXIN MEMORY TECHNOLOGIES, INC., Hefei City (CN)

(72) Inventor: Huan LU, Hefei City (CN)

(21) Appl. No.: 17/807,283

(22) Filed: Jun. 16, 2022

Related U.S. Application Data
(63) Continuation of application No. PCT/CN2022/087595, filed on Apr. 19, 2022.

(30) Foreign Application Priority Data
Mar. 8, 2022 (CN) 202210228007.3

(51) Int. Cl. G01R 31/317; G01R 31/319; G01R 31/3193; G01R 31/3183; G01R 31/3185

(52) U.S. Cl. CPC G01R 31/31711; G01R 31/31901; G01R 31/31937; G01R 31/31835; G01R 31/318569

(57) ABSTRACT

Embodiments of the present disclosure relate to a method and an apparatus of analyzing data, and a storage medium. The method of analyzing data includes: obtaining a single shmoo plot of each pin of a memory particle; and constructing an integrated shmoo plot of the memory particle based on the single shmoo plot of each of the pins, wherein each test point of the integrated shmoo plot is marked with a pass proportion, and the pass proportion is configured to represent a proportion of a quantity of passed single shmoo plots at a corresponding test point to a total quantity of the single shmoo plots.

### CROSS-REFERENCE TO RELATED APPLICATIONS

This is a continuation of International Application No. PCT/CN2022/087595, filed on Apr. 19, 2022, which claims the priority to Chinese Patent Application 202210228007.3, titled “METHOD AND APPARATUS OF ANALYZING DATA, AND STORAGE MEDIUM” and filed with the China National Intellectual Property Administration (CNIPA) on Mar. 8, 2022. The entire contents of International Application No. PCT/CN2022/087595 and Chinese Patent Application 202210228007.3 are incorporated herein by reference.

### TECHNICAL FIELD

Embodiments of the present disclosure relate to the technical field of semiconductor storage, and specifically, to a method and an apparatus of analyzing data, and a storage medium.

### BACKGROUND

With the rapid development of integrated circuit (IC) manufacturing process, the market puts forward higher requirements for output efficiency and quality of semiconductor storage products. In order to improve the output quality, semiconductor storage products are generally tested in batches before delivery.

However, test data of different pins of a semiconductor memory particle is very miscellaneous. The traditional method for manually comparing and analyzing the test data makes it difficult to quickly distinguish a feature difference between different memory particles and trace a root cause of the difference, and inevitably introduces a manual operation error, resulting in low data analysis efficiency and prolonging a product test cycle and output cycle.

### SUMMARY

Embodiments of the present disclosure provide a method and an apparatus of analyzing data, and a storage medium.

According to some embodiments, a first aspect of the present disclosure provides a method of analyzing data, including: obtaining a single shmoo plot of each pin of a memory particle; and constructing an integrated shmoo plot of the memory particle based on the single shmoo plot of each of the pins, wherein each test point of the integrated shmoo plot is marked with a pass proportion, and the pass proportion is configured to represent a proportion of a quantity of passed single shmoo plots at a corresponding test point to a total quantity of the single shmoo plots.

According to some embodiments, a second aspect of the present disclosure provides a method of analyzing data, including: obtaining a single shmoo plot of any one of a plurality of memory particles; and constructing an integrated shmoo plot of a memory based on single shmoo plots of the memory particles, wherein each test point of the integrated shmoo plot is marked with a third identifier, and the third identifier is configured to represent a code of a passed memory particle at a corresponding test point.

According to some embodiments, a third aspect of the present disclosure provides an apparatus of analyzing data, including a memory and a processor, wherein the memory stores a computer program, and the processor executes the computer program to implement: obtaining a single shmoo plot of each pin of a memory particle; and constructing an integrated shmoo plot of the memory particle based on the single shmoo plot of each of the pins, wherein each test point of the integrated shmoo plot is marked with a pass proportion, and the pass proportion is configured to represent a proportion of a quantity of passed single shmoo plots at a corresponding test point to a total quantity of the single shmoo plots.

According to some embodiments, a fourth aspect of the present disclosure provides a computer-readable storage medium, storing a computer program, wherein the computer program is executed by a processor to implement the method according to any one of the embodiments of the present disclosure.

Details of one or more embodiments of the present disclosure will be illustrated in the following drawings and description. Other features, objectives, and advantages of the present disclosure become evident in the specification, claims, and accompanying drawings.

### BRIEF DESCRIPTIONS OF THE DRAWINGS

To describe the technical solutions in the embodiments of the present disclosure more clearly, the accompanying drawings required to describe the embodiments are briefly described below. Apparently, the accompanying drawings described below are only some embodiments of the present disclosure. A person of ordinary skill in the art may further obtain accompanying drawings of other embodiments based on these accompanying drawings without creative efforts.

FIG. 1 is a schematic flowchart of a method of analyzing data according to an embodiment of the present disclosure;

FIG. 2a schematically illustrates an original shmoo plot of a pin of a memory particle;

FIG. 2b schematically illustrates an integrated shmoo plot of a memory particle according to an embodiment;

FIG. 3 is a schematic flowchart of a method of analyzing data according to another embodiment of the present disclosure;

FIG. 4a schematically illustrates an integrated shmoo plot of a memory particle according to another embodiment;

FIG. 4b schematically illustrates an integrated shmoo plot of a memory particle according to still another embodiment;

FIG. 4c schematically illustrates an integrated shmoo plot of a memory particle according to yet another embodiment;

FIG. 5 is a schematic flowchart of a method of analyzing data according to still another embodiment of the present disclosure;

FIG. 6a schematically illustrates an integrated shmoo plot of a memory particle with an edge defect according to an embodiment;

FIG. 6b schematically illustrates an integrated shmoo plot of a memory particle with an edge defect according to another embodiment;

FIG. 7 schematically illustrates an integrated shmoo plot of a memory particle with a void defect according to an embodiment;

FIG. 8 schematically illustrates an integrated shmoo plot of a memory particle with a voltage linearity defect according to an embodiment;

FIG. 9 schematically illustrates an integrated shmoo plot of a memory particle with a frequency linearity defect according to an embodiment;

FIG. 10 schematically illustrates an integrated shmoo plot of a memory particle with a void defect and a voltage linearity defect according to an embodiment;

FIG. 11 is a schematic flowchart of a method of analyzing data according to yet another embodiment of the present disclosure;

FIG. 12a schematically illustrates a single shmoo plot of a memory particle according to an embodiment;

FIG. 12b schematically illustrates an integrated shmoo plot of a memory according to an embodiment;

FIG. 13 is a schematic structural diagram of an apparatus of analyzing data according to an embodiment of the present disclosure;

FIG. 14 is a schematic structural diagram of an apparatus of analyzing data according to another embodiment of the present disclosure;

FIG. 15 is a schematic structural diagram of an apparatus of analyzing data according to still another embodiment of the present disclosure; and

FIG. 16 is a schematic structural diagram of an apparatus of analyzing data according to an embodiment of the present disclosure.

### DETAILED DESCRIPTION

To facilitate the understanding of the present disclosure, the present disclosure is described more completely below with reference to the related accompanying drawings. Preferred embodiments of the represent disclosure are shown in the accompanying drawings. However, the present disclosure may be embodied in various forms without being limited to the embodiments described herein. On the contrary, these embodiments are provided to make the present disclosure more thorough and comprehensive.

Unless otherwise defined, all technical and scientific terms used in the specification have the same meaning as commonly understood by those skilled in the technical field of the present disclosure. The terms used in the specification of the present disclosure are merely for the purpose of describing specific embodiments, rather than to limit the present disclosure. The term “and/or” used in the specification includes any and all combinations of one or more of the associated listed items.

In the case of using “include”, “have”, and “contain” described in the specification, another component can be added unless explicit qualifiers such as “only” and “composed of” are used. Unless mentioned contrarily, a term in a singular form may include a plural form and cannot be understood as one.

It is should be understood that the terms such as “first” and “second” used herein may be used to describe various elements, but these elements are not limited by these terms. Instead, these terms are merely intended to distinguish one element from another. For example, without departing from the scope of the present disclosure, a first element may be referred to as a second element, and similarly, a second element may be referred to as a first element.

In the present disclosure, unless otherwise clearly specified, the terms “mounted to”, “connected with” and “connected to” should be understood in a broad sense. For example, “connected to” may be a fixed connection, a detachable connection or an integrated connection, may be a direct connection or an indirect connection via an intermediate medium, or may be intercommunication between two components. Those of ordinary skill in the art may understand specific meanings of the foregoing terms in the present disclosure based on a specific situation.

It should be noted that, in the present disclosure, the term “memory particle” may include any one of a memory chip, a memory, and a memory device, and the term “pin” may be a data transmission port of the “memory particle”.

A shmoo plot is an effective tool for analyzing features of a memory chip. In failure analysis, the shmoo plot compares different parameters such as a numerical curve relationship between a scanning voltage and a scanning frequency to help locate a root cause of a failure and find out a potential problem in chip design. The scanning frequency is a reciprocal of a scanning cycle. However, due to complexity of shmoo data of different pins of a memory particle such as the memory chip, a task of manually drawing a single shmoo plot of each pin is very heavy, and there are a certain quantity of unavoidable manual operation errors, which makes it difficult to quickly distinguish a feature difference between different pins and trace back to a root cause. In addition, accuracy of a test result depends on experience and proficiency of a test engineer, resulting in low failure analysis efficiency and making it difficult to guarantee accuracy of a failure analysis result.

The embodiments of the present disclosure are intended to provide a method and an apparatus of analyzing data, and a storage medium to automatically generate an integrated shmoo plot of a memory particle, and display pass proportions of test data of different pins on the integrated shmoo plot to intuitively present rules and differences of the test data. In this way, related staff can quickly distinguish a feature difference between different memory particles and trace a root cause of the difference. This avoids a manual operation error, and makes it more efficient and intelligent to analyze test data of the memory particle.

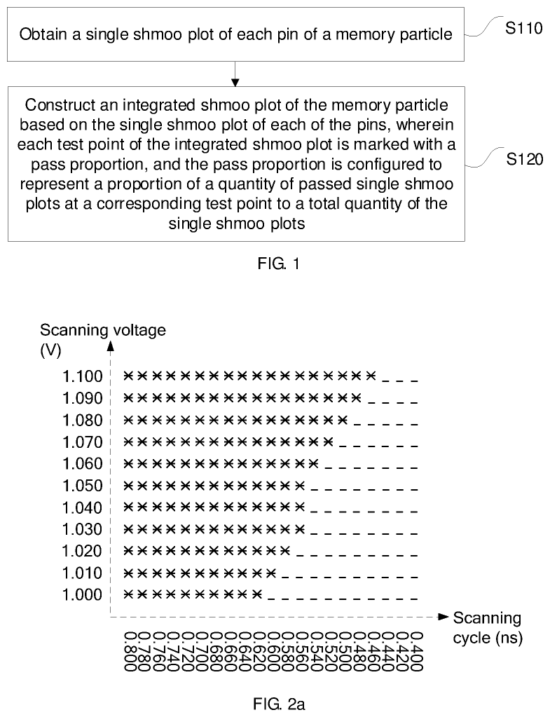

As an example, referring to FIG. 1, a method of analyzing data includes:
Step S110: Obtain a single shmoo plot of each pin of a memory particle.
Step S120: Construct an integrated shmoo plot of the memory particle based on the single shmoo plot of each of the pins, where each test point of the integrated shmoo plot is marked with a pass proportion, and the pass proportion is configured to represent a proportion of a quantity of passed single shmoo plots at the corresponding test point to a total quantity of single shmoo plots.

Specifically, the integrated shmoo plot of the memory particle is automatically constructed based on the single shmoo plot of each of the pins of the memory particle. Each test point of the integrated shmoo plot is marked with the pass proportion. For example, the pass proportion may be expressed by a digital identifier and/or a name identifier of a pin. The pass proportion may be configured to represent at least the proportion of the quantity of passed single shmoo plots at the corresponding test point to the total quantity of single shmoo plots. For example, if the total quantity of single shmoo plots of the pins of the memory particle is N, a pass proportion of any test point in the integrated shmoo plot at least includes a proportion R of a quantity (M) of passed single shmoo plots at the test point to the total quantity (N) of single shmoo plots (N), namely, R=M/N, where M and N are positive integers, and R∈[0, 1]. Whether a single shmoo plot is a passed shmoo plot can be determined by determining whether area of a pass region in the single shmoo plot exceeds preset standard area. A single shmoo plot with area of a pass region greater than or equal to the preset standard area can be determined as the passed single shmoo plot, and a single shmoo plot with area of a pass region less than the preset standard area can be determined as a failed single shmoo plot.

The integrated shmoo plot of the memory particle is automatically generated based on the single shmoo plot of each of the pins of the memory particle, which avoids a manual operation error and improves test efficiency. The pass proportion of each test point in the integrated shmoo plot intuitively presents the proportion of the quantity of passed single shmoo plots at the corresponding test point to the total quantity of single shmoo plots to related staff, such that the related staff can easily determine common features or regular features of test data based on repeated pass proportions or a change trend of the pass proportion in the integrated shmoo plot, determine a feature difference between different pins of the memory particle based on a difference between pass proportions in the integrated shmoo plot, and trace a root cause of the difference, for example, a design defect or a manufacturing defect. This makes it more efficient and intelligent to analyze the test data of the memory particle.

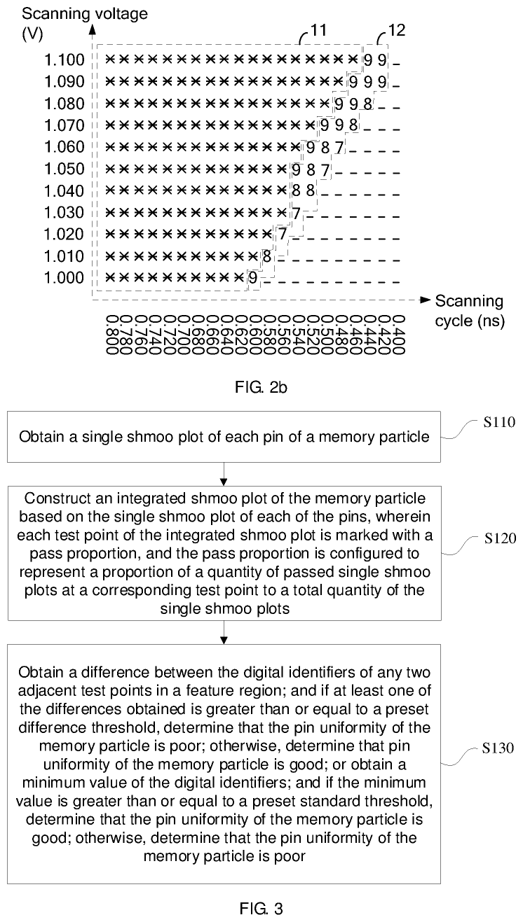

As an example, referring to FIG. 2a, FIG. 2a schematically illustrates a single shmoo plot, also referred to as an original shmoo plot, of a pin of a memory particle. All points in a pass region of the original shmoo plot are passed points. In the original shmoo plot, a passed point is represented by “ [symbol] ” and a failed point is represented by “-”. The original shmoo plot can only roughly display the passed point and the failed point, and the memory particle has a plurality of unused pins. Therefore, there are a large quantity of original shmoo plots of different pins of the memory particle, which makes it difficult for test personnel to quickly distinguish a feature difference between different memory particles and trace a root cause of the difference. Because different staff have different work proficiency, experience, and personal standards, a manual operation error inevitably exists in an analysis result of the original shmoo plot, and efficiency of manual data analysis is low, which prolongs a product test cycle and output cycle.

As an example, referring to FIG. 2b, FIG. 2b schematically illustrates the integrated shmoo plot of the memory particle based on the single shmoo plot of each of the pins of the memory particle. Each test point of the integrated shmoo plot is marked with the pass proportion, and the pass proportion is configured to represent the proportion of the quantity of passed single shmoo plots at the corresponding test point to the total quantity of single shmoo plots. The integrated shmoo plot includes a feature region 12 and a pass region 11 that are partially overlapped. The pass region 11 includes a common pass region of the single shmoo plots. A pass proportion of the test point in the pass region 11 is 100%, and the passed point is represented by “ [symbol] ”. A pass proportion of the test point in the feature region 12 is greater than 0 and less than 100%, the feature region 12 has at least two types of first identifiers such as digital identifiers for representing the pass proportion, and different first identifiers represent different pass proportions. The failed point is represented by “-”, and a pass proportion of the failed point is 0. According to this embodiment, the related staff can easily explore the common features of the test data based on the common pass region of the single shmoo plots, and determine performance of the memory particle; and determine the feature difference between the different pins of the memory particle based on the difference between the pass proportions in the feature region, and trace the root cause of the difference.

As an example, still referring to FIG. 2b, it can be controlled that a corresponding digital identifier is displayed for each test point in the feature region 12. For example, it can be controlled that “0” is displayed for a test point with a pass proportion greater than 0 and less than 10%, “1” is displayed for a test point with a pass proportion greater than or equal to 10% and less than 20%, “2” is displayed for a test point with a pass proportion greater than or equal to 20% and less than 30%, “3” is displayed for a test point with a pass proportion greater than or equal to 30% and less than 40%, “4” is displayed for a test point with a pass proportion greater than or equal to 40% and less than 50%, “5” is displayed for a test point with a pass proportion greater than or equal to 50% and less than 60%, “6” is displayed for a test point with a pass proportion greater than or equal to 60% and less than 70%, “7” is displayed for a test point with a pass proportion greater than or equal to 70% and less than 80%, “8” is displayed for a test point with a pass proportion greater than or equal to 80% and less than 90%, and “9” is displayed for a test point with a pass proportion greater than or equal to 90% and less than 100%. According to this embodiment, the related staff can easily compare the digital identifier of each test point, determine the feature difference between the different pins of the memory particle based on a comparison result, and trace the root cause of the difference.

As an example, referring to FIG. 3, the method of analyzing data further includes the following step to determine pin uniformity of the memory particle.
Step S130: Obtain a difference between digital identifiers of any two adjacent test points in the feature region; and if at least one of obtained differences is greater than or equal to a preset difference threshold, determine that the pin uniformity of the memory particle is poor; otherwise, determine that the pin uniformity of the memory particle is good; or obtain a minimum value of digital identifiers in the feature region; and if the minimum value is greater than or equal to a preset standard threshold, determine that the pin uniformity of the memory particle is good; otherwise, determine that the pin uniformity of the memory particle is poor.

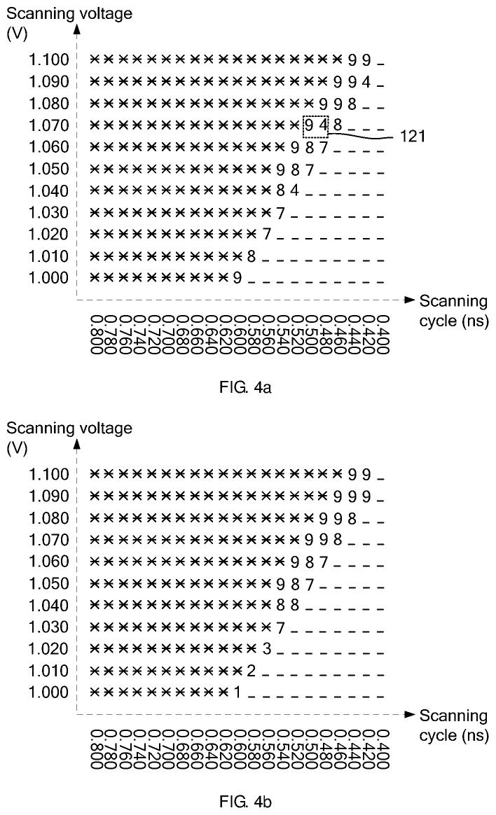

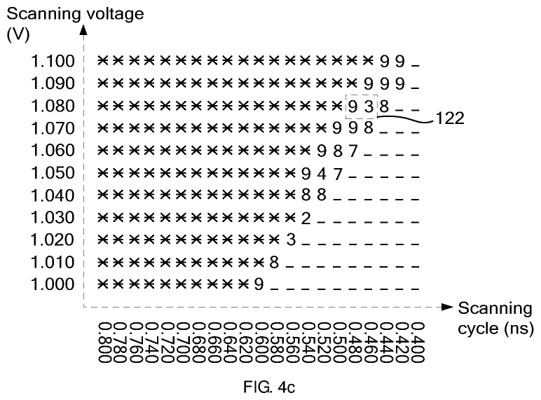

Specifically, referring to FIG. 4a, after it is controlled that the corresponding digital identifier is displayed for each test point in the feature region 12, the difference between the digital identifiers of the any two adjacent test points in the feature region is obtained. If the at least one of the obtained differences is greater than or equal to the preset difference threshold such as 4, for example, if a difference between digital identifiers of two adjacent test points in a first feature subregion 121 is 5, greater than the preset difference threshold 4, it is determined that the pin uniformity of the memory particle is poor; otherwise, it is determined that the pin uniformity of the memory particle is good. This makes data analysis more intelligent and efficient.

Specifically, referring to FIG. 4b, the preset standard threshold is, for example, 5. After it is controlled that the corresponding digital identifier is displayed for each test point in the feature region 12, the minimum value of the digital identifiers in the feature region is obtained. If the obtained minimum value is 1, less than 5, it is determined that the pin uniformity of the memory particle is poor; if the obtained minimum value is not less than 5, it is determined that the pin uniformity of the memory particle is good. This makes data analysis more intelligent and efficient.

Specifically, referring to FIG. 4c, for example, the preset difference threshold is 4, and the preset standard threshold is 5. When a difference between digital identifiers of two adjacent test points in a second feature subregion 122 is 6, greater than 4, and the minimum value of the digital identifiers in the feature region is 2, less than 5, it is determined that the pin uniformity of the memory particle is poor. This makes data analysis more intelligent and efficient.

Those skilled in the art can undoubtedly make sure that the specific values of the preset difference threshold or the preset standard threshold in the above embodiments are intended to provide illustrative description, and there may be different values in different embodiments.

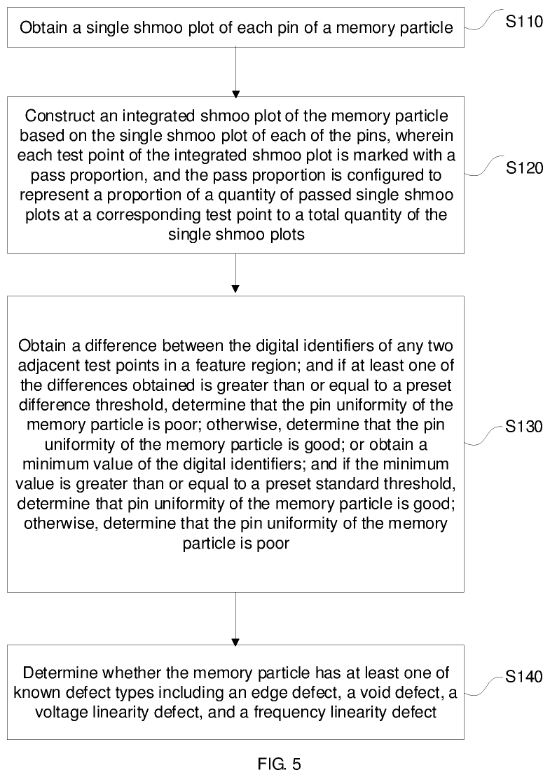

As an example, referring to FIG. 5, the method of analyzing data further includes the following step:
Step S140: Determine whether the memory particle has at least one of known defect types including an edge defect, a void defect, a voltage linearity defect, and a frequency linearity defect.

Specifically, in some embodiments, before step S140 is performed, pre-stored area of a standard pass region in a mode register of the memory particle may be obtained to further determine whether area of the pass region of the integrated shmoo plot exceeds the area of the standard pass region. If the area of the pass region of the integrated shmoo plot is less than the area of the standard pass region, it can be determined that the memory particle has a defect, and step S140 is further performed to determine whether the memory particle has the at least one of the known defect types including the edge defect, the void defect, the voltage linearity defect, and the frequency linearity defect.

As an example, the method of analyzing data further includes determining whether the memory particle has the edge defect:
Step S1411: Obtain the standard pass region of the integrated shmoo plot of the memory particle.
Step S1412: Determine, as a first coordinate axis (horizontal axis), an axis of symmetry that is of the standard pass region and extends along a frequency scanning direction, and determine, as a second coordinate axis (vertical axis), an axis of symmetry that is of the standard pass region and extends along a voltage scanning direction or a straight line of a boundary line that is of the standard pass region and extends along the voltage scanning direction.
Step S1413: Obtain an intersection point of a boundary line of the feature region and the first coordinate axis, and obtain a distance between the intersection point and a vertical point of coordinate axes, wherein the vertical point of coordinate axes is a vertical point of the first coordinate axis and the second coordinate axis or an intersection point of the first coordinate axis and the second coordinate axis.
Step S1414: If the distance is greater than or equal to a preset distance threshold, determine that the memory particle has the edge defect.

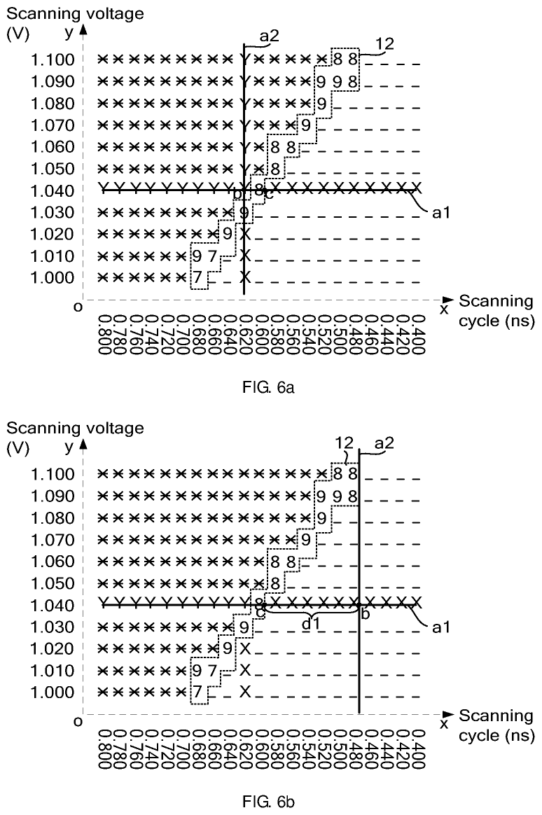

Specifically, referring to FIG. 6a, the standard pass region (not shown in the figure) of the integrated shmoo plot of the memory particle is obtained; the axis of symmetry that is of the standard pass region and extends along the frequency scanning direction (ox direction) is determined as the first coordinate axis a1, and the axis of symmetry that is of the standard pass region and extends along the voltage scanning direction (oy direction) is determined as the second coordinate axis a2; the intersection point c of the boundary line of the feature region 12 and the first coordinate axis a1 is obtained, and the distance d1 between the intersection point c and the vertical point b of coordinate axes, wherein the vertical point b of coordinate axes is the vertical point of the first coordinate axis a1 and the second coordinate axis a2 or the intersection point of the first coordinate axis a1 and the second coordinate axis a2; and if the distance d1 is greater than or equal to the preset distance threshold d0, it is determined that the memory particle has the edge defect. This embodiment can intelligently determine, based on the integrated shmoo plot of the memory particle, whether the memory particle has the edge defect.

As an example, referring to FIG. 6b, the following can be performed to determine whether the memory particle has the edge defect: obtaining the standard pass region (not shown in the figure) of the integrated shmoo plot of the memory particle; determining, as the first coordinate axis a1, the axis of symmetry that is of the standard pass region and extends along the frequency scanning direction (ox direction), and determining, as the second coordinate axis a2, the straight line of the boundary line that is of the standard pass region and extends along the voltage scanning direction (oy direction); obtaining the intersection point c of the boundary line of the feature region 12 and the first coordinate axis a1, and obtaining the distance d1 between the intersection point c and the vertical point b of coordinate axes, wherein the vertical point b of coordinate axes is the vertical point of the first coordinate axis a1 and the second coordinate axis a2; and if the distance d1 is greater than or equal to the preset distance threshold, determining that the memory particle has the edge defect. This embodiment can intelligently determine, based on the integrated shmoo plot of the memory particle, whether the memory particle has the edge defect.

As an example, the method of analyzing data further includes determining whether the memory particle has the void defect:
Step S1421: Determine whether there is a failed region in the pass region, where the failed region contains a plurality of consecutive failed points.
Step S1422: If yes, determine whether any failed region includes at least two consecutive failed points in a voltage scanning direction and at least two consecutive failed points in a frequency scanning direction.
Step S1423: If yes, determine that the memory particle has the void defect.

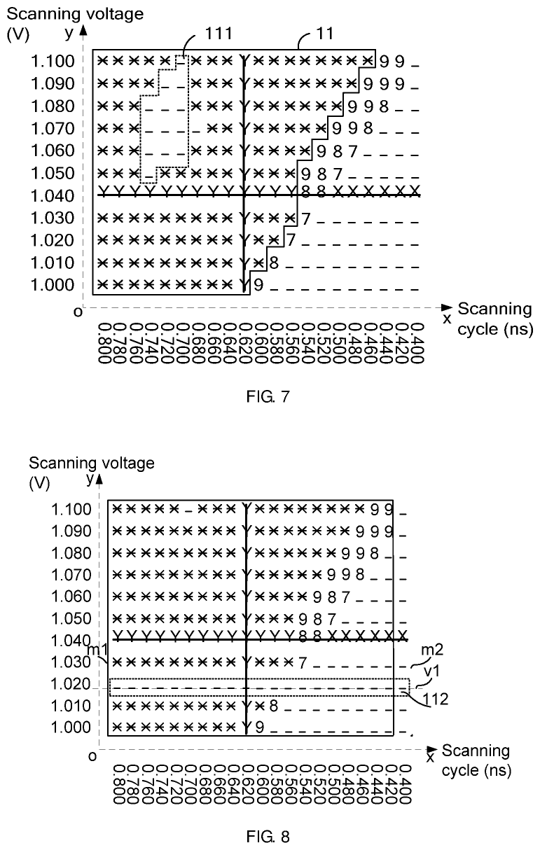

As an example, referring to FIG. 7, whether there is the failed region 111 in the pass region 11 is determined, where the failed region 111 contains the plurality of consecutive failed points, the failed point is represented by “-”, and the pass proportion of the failed point is 0; if there is the failed region 111 in the pass region 11, whether the any failed region 111 includes the at least two consecutive failed points in the voltage scanning direction (oy direction) and the at least two consecutive failed points in the frequency scanning direction (ox direction) is determined, where a frequency is a reciprocal of a cycle; and if the any failed region 111 includes the at least two consecutive failed points in the voltage scanning direction (oy direction) and the at least two consecutive failed points in the frequency scanning direction (ox direction), it is determined that the memory particle has the void defect. This embodiment can intelligently determine, based on the integrated shmoo plot of the memory particle, whether the memory particle has the void defect.

As an example, the method of analyzing data further includes determining whether the memory particle has the voltage linearity defect:
Step S1431: Determine whether there is a voltage linearity defect region in the integrated shmoo plot, where the voltage linearity defect region includes at least one voltage failure line that extends along a frequency scanning direction and intersects with two opposite boundary lines of the integrated shmoo plot, and each test point on the voltage failure line is a failed point.
Step S1432: If yes, determine that the memory particle has the voltage linearity defect.

As an example, referring to FIG. 8, whether there is the voltage linearity defect region 112 in the integrated shmoo plot is determined, where the voltage linearity defect region 112 includes the at least one voltage failure line v1 that extends along the frequency scanning direction (ox direction) and intersects with a left boundary line m1 and a right boundary line m2 of the integrated shmoo plot, the right boundary m2 is a boundary line that is of the feature region of the integrated shmoo plot of the memory particle and close to the failed region, each test point on the voltage failure line v1 is a failed point represented by “-”, and the pass proportion of the failed point is 0; and if yes, it is determined that the memory particle has the voltage linearity defect. This embodiment can intelligently determine, based on the integrated shmoo plot of the memory particle, whether the memory particle has the voltage linearity defect. As an example, the method of analyzing data further includes determining whether the memory particle has the frequency linearity defect:
Step S1441: Determine whether there is a frequency linearity defect region in the integrated shmoo plot, where the frequency linearity defect region includes at least one frequency failure line that extends along a voltage scanning direction and intersects with two opposite boundary lines of the integrated shmoo plot, and each test point on the voltage failure line is a failed point.
Step S1442: If yes, determine that the memory particle has the frequency linearity defect.

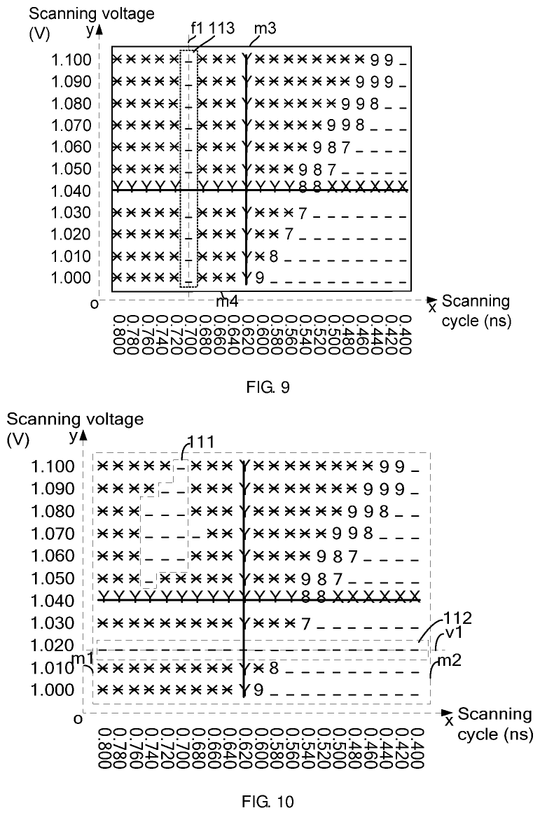

As an example, referring to FIG. 9, whether there is the frequency linearity defect region 113 in the integrated shmoo plot is determined, where the frequency linearity defect region 113 includes the at least one frequency failure line f1 that extends along the voltage scanning direction (oy direction) and intersects with an upper boundary line m3 and a lower boundary line m4 of the integrated shmoo plot, each test point on the frequency failure line f1 is a failed point represented by “-”, and the pass proportion of the failed point is 0; and if yes, it is determined that the memory particle has the frequency linearity defect. This embodiment can intelligently determine, based on the integrated shmoo plot of the memory particle, whether the memory particle has the frequency linearity defect.

As an example, referring to FIG. 10, in a process of determining whether the memory particle has the at least one of the known defect types including the edge defect, the void defect, the voltage linearity defect, and the frequency linearity defect, it is determined that the memory particle has both the void defect and the voltage linearity defect when it is determined that there is the failed region 111 in the pass region and that there is the voltage linearity defect region 112 in the integrated shmoo plot, where the failed region 111 contains the plurality of consecutive failed points, and includes the at least two consecutive failed points in the voltage scanning direction (oy direction) and the at least two consecutive failed points in the frequency scanning direction (ox direction), the failed point is represented by “-”, and the pass proportion of the failed point is 0; and the voltage linearity defect region 112 includes the at least one voltage failure line v1 that extends along the frequency scanning direction (ox direction) and intersects with the left boundary line m1 and the right boundary line m2 of the integrated shmoo plot, and each test point on the voltage failure line v1 is a failed point.

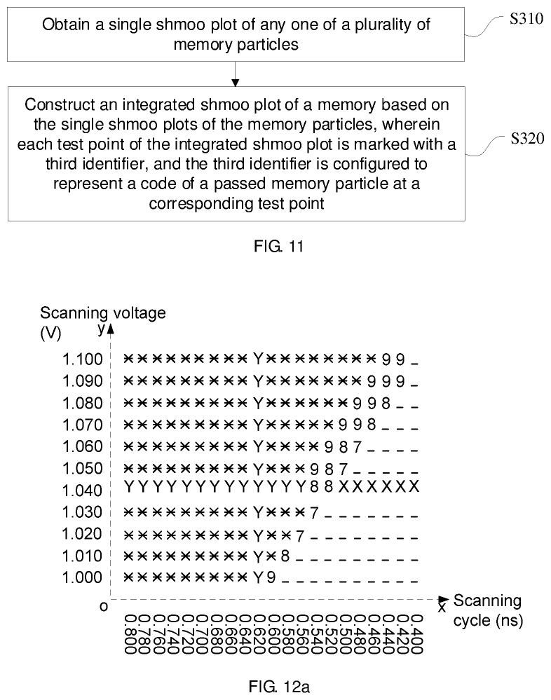

As an example, referring to FIG. 11, a method of analyzing data includes:
Step S310: Obtain a single shmoo plot of any one of a plurality of memory particles.
Step S320: Construct an integrated shmoo plot of a memory based on single shmoo plots of the memory particles, where each test point of the integrated shmoo plot is marked with a third identifier, and the third identifier is configured to represent a code of a passed memory particle at the corresponding test point.

FIG. 12a schematically illustrates a single shmoo plot of a memory particle. Specifically, after the single shmoo plot of the any one of the memory particles is obtained, the integrated shmoo plot of the memory is constructed based on the single shmoo plots of the memory particles, as shown in FIG. 12b. Each test point of the integrated shmoo plot of the memory is marked with the third identifier, and the third identifier is configured to represent the code of the passed memory particle at the corresponding test point, for example, code A and code B are codes of two different memory particles. In the integrated shmoo plot of the memory, a pass proportion of the test point may be 100%, the passed point is represented by “ [symbol] ”, a failed point is represented by “-”, and a pass proportion of the failed point may be 0. This embodiment makes it easy to intuitively find an edge difference between different memory particles based on the integrated shmoo plot of the memory.

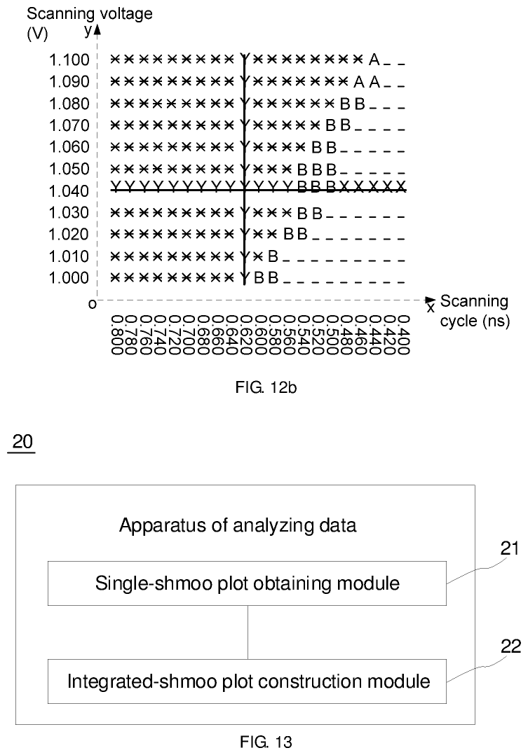

As an example, referring to FIG. 13, an apparatus of analyzing data 20 includes a single-shmoo plot obtaining module 21 and an integrated-shmoo plot construction module 22. The single-shmoo plot obtaining module 21 is configured to obtain a single shmoo plot of each pin of a memory particle; and the integrated-shmoo plot construction module 22 is configured to construct an integrated shmoo plot of the memory particle based on the single shmoo plot of each of the pins, where each test point of the integrated shmoo plot is marked with a pass proportion, and the pass proportion is configured to represent a proportion of a quantity of passed single shmoo plots at the corresponding test point to a total quantity of single shmoo plots. The integrated-shmoo plot construction module automatically generates the integrated shmoo plot of the memory particle based on the single shmoo plot of each of the pins of the memory particle. The pass proportion of each test point in the integrated shmoo plot intuitively presents the proportion of the quantity of passed single shmoo plots at the corresponding test point to the total quantity of single shmoo plots to related staff, such that the related staff can easily determine common features or regular features of test data based on repeated pass proportions or a change trend of the pass proportion in the integrated shmoo plot, determine a feature difference between different pins of the memory particle based on a difference between pass proportions in the integrated shmoo plot, and trace a root cause of the difference. This avoids a manual operation error, and makes it more efficient and intelligent to analyze the test data of the memory particle.

As an example, the integrated shmoo plot includes a feature region and a pass region that are partially overlapped. The pass region includes a common pass region of the single shmoo plots, and a pass proportion of the test point in the common pass region is 100%. A pass proportion of the test point in the feature region is greater than 0 and less than 100%, the feature region has at least two types of first identifiers such as digital identifiers for representing the pass proportion, and different first identifiers represent different pass proportions. According to this embodiment, the related staff can easily explore the common features of the test data based on the common pass region of the single shmoo plots, and determine performance of the memory particle; and determine the feature difference between the different pins of the memory particle based on the difference between the pass proportions in the feature region, and trace the root cause of the difference.

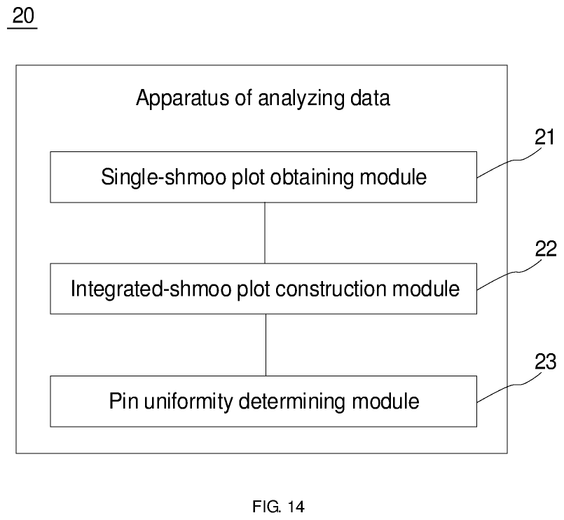

As an example, referring to FIG. 14, the first identifier includes the digital identifier, and the apparatus of analyzing data 20 further includes a pin uniformity determining module 23. The pin uniformity determining module 23 is configured to: compare digital identifiers of two adjacent test points in the feature region, or obtain a minimum value of digital identifiers and compare the minimum value with a preset standard threshold; and determine pin uniformity of the memory particle based on a comparison result. This makes data analysis more intelligent and efficient. For example, it can be controlled that “0” is displayed for a test point with a pass proportion greater than 0 and less than 10%, “1” is displayed for a test point with a pass proportion greater than or equal to 10% and less than 20%, “2” is displayed for a test point with a pass proportion greater than or equal to 20% and less than 30%, “3” is displayed for a test point with a pass proportion greater than or equal to 30% and less than 40%, “4” is displayed for a test point with a pass proportion greater than or equal to 40% and less than 50%, “5” is displayed for a test point with a pass proportion greater than or equal to 50% and less than 60%, “6” is displayed for a test point with a pass proportion greater than or equal to 60% and less than 70%, “7” is displayed for a test point with a pass proportion greater than or equal to 70% and less than 80%, “8” is displayed for a test point with a pass proportion greater than or equal to 80% and less than 90%, and “9” is displayed for a test point with a pass proportion greater than or equal to 90% and less than 100%. A difference between digital identifiers of any two adjacent test points in the feature region is obtained. If at least one of obtained differences is greater than or equal to a preset difference threshold, for example, 4, it is determined that the pin uniformity of the memory particle is poor; otherwise, it is determined that the pin uniformity of the memory particle is good. Alternatively, the minimum value of the digital identifiers in the feature region is obtained. If the minimum value is greater than or equal to the preset standard threshold, for example, 5, it is determined that the pin uniformity of the memory particle is good; or if the minimum value is not greater than or equal to the preset standard threshold, it is determined that the pin uniformity of the memory particle is poor.

As an example, the test point in the feature region is further marked with a second identifier for representing a corresponding pin, for example, a name identifier, such that the related staff can intuitively distinguish different pins, so as to determine the feature difference between the different pins of the memory particle based on the difference between the pass proportions in the feature region, and trace the root cause of the difference.

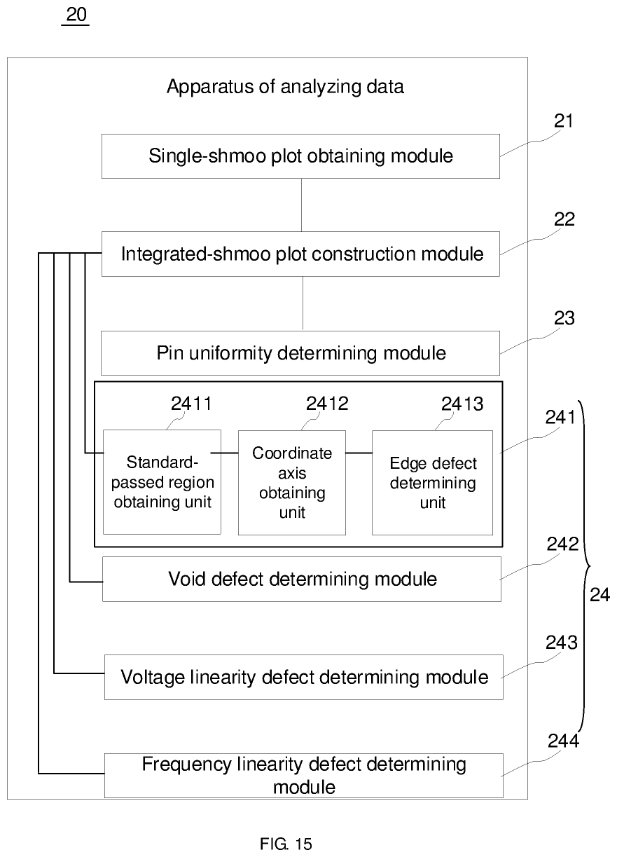

As an example, referring to FIG. 15, a defect type determining module 24 includes an edge defect determining module 241. The edge defect determining module 241 includes a standard-pass region obtaining unit 2411, a coordinate axis obtaining unit 2412, and an edge defect determining unit 2413. The standard-pass region obtaining unit 2411 is configured to obtain a standard pass region of the integrated shmoo plot of the memory particle; the coordinate axis obtaining unit 2412 is configured to: determine, as a first coordinate axis, an axis of symmetry that is of the standard pass region and extends along a frequency scanning direction, and determine, as a second coordinate axis, an axis of symmetry that is of the standard pass region and extends along a voltage scanning direction or a straight line of a boundary line that is of the standard pass region and extends along the voltage scanning direction; and the edge defect determining unit 2413 is configured to: obtain an intersection point of a boundary line of the feature region and the first coordinate axis, and obtain a distance between the intersection point and a vertical point of coordinate axes, wherein the vertical point of coordinate axes is a vertical point of the first coordinate axis and the second coordinate axis; and if the distance is greater than or equal to a preset distance threshold, determine that the memory particle has an edge defect. This embodiment can intelligently determine, based on the integrated shmoo plot of the memory particle, whether the memory particle has the edge defect.

As an example, still referring to FIG. 15, the apparatus of analyzing data further includes a void defect determining module 242. The void defect determining module 242 is configured to: determine whether there is a failed region in the pass region, where the failed region contains a plurality of consecutive failed points; if yes, determine whether any failed region includes at least two consecutive failed points in a voltage scanning direction and at least two consecutive failed points in a frequency scanning direction; and if yes, determine that the memory particle has a void defect. This embodiment can intelligently determine, based on the integrated shmoo plot of the memory particle, whether the memory particle has the void defect.

As an example, still referring to FIG. 15, the apparatus of analyzing data further includes a voltage linearity defect determining module 243. The voltage linearity defect determining module 243 is configured to: determine whether there is a voltage linearity defect region in the integrated shmoo plot, where the voltage linearity defect region includes at least one voltage failure line that extends along a frequency scanning direction and intersects with two opposite boundary lines of the integrated shmoo plot, and each test point on the voltage failure line is a failed point; and if yes, determine that the memory particle has a voltage linearity defect. This embodiment can intelligently determine, based on the integrated shmoo plot of the memory particle, whether the memory particle has the voltage linearity defect.

As an example, still referring to FIG. 15, the apparatus of analyzing data further includes a frequency linearity defect determining module 244. The frequency linearity defect determining module 244 is configured to: determine whether there is a frequency linearity defect region in the integrated shmoo plot, where the frequency linearity defect region includes at least one frequency failure line that extends along a voltage scanning direction and intersects with two opposite boundary lines of the integrated shmoo plot, and each test point on the frequency failure line is a failed point; and if yes, determine that the memory particle has a frequency linearity defect. This embodiment can intelligently determine, based on the integrated shmoo plot of the memory particle, whether the memory particle has the frequency linearity defect.

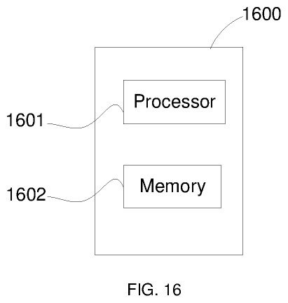

As an example, referring to FIG. 16, an apparatus of analyzing data 1600 includes a processor 1601 and a memory 1602, wherein the memory 1602 stores a computer program executable by the processor; and the processor 1601 executes the computer program to implement the method according to any one of the above embodiments of the present disclosure.

In an exemplary embodiment, a non-transitory computer-readable storage medium including instructions is provided. Referring to FIG. 16, for example, the non-transitory computer-readable storage medium may be the memory 1602 including instructions. The foregoing instructions may be executed by the processor 1601 of the apparatus of analyzing data 1600 to complete the foregoing method. For example, the non-transitory computer-readable storage medium may be a ROM, a RAM, a CD-ROM, a magnetic tape, a floppy disk, an optical data storage device, or the like.

In an embodiment of the present disclosure, a computer-readable storage medium is provided. The computer-readable storage medium stores a computer program, and the computer program is executed by a processor to implement the method according to any one of the above embodiments of the present disclosure.

Persons skilled in the art should understand that the embodiments of the present disclosure may be provided as a method, an apparatus (device), or a computer program product. Therefore, the present disclosure may use a form of hardware only examples, software only examples, or examples with a combination of software and hardware. Moreover, the present disclosure may be in a form of a computer program product that is implemented on one or more computer-usable storage media that include computer-usable program code. The computer storage media include volatile and non-volatile, removable and non-removable media implemented in any method or technology for storing information (such as computer-readable instructions, data structures, program modules, or other data), including but not limited to, a RAM, a ROM, an EEPROM, a flash memory or other storage technologies, a CD-ROM, a digital versatile disk (DVD) or other optical disc storage, a magnetic cassette, a magnetic tape, magnetic disk storage or other magnetic storage apparatuses, or any other medium that can be used to store desired information and can be accessed by a computer. In addition, as is well known to persons of ordinary skill in the art, the communication media usually contain computer-readable instructions, data structures, program modules, or other data in modulated data signals such as carrier waves or other transmission mechanisms, and may include any information transfer medium.

Although the steps in the flowcharts of FIG. 1, FIG. 3, FIG. 5, and FIG. 11 are sequentially displayed according to the arrows, these steps are not necessarily executed in the order indicated by the arrows. Unless clearly described otherwise, the execution order of the steps is not strictly limited, and these steps may be executed in other orders. Moreover, at least some of the steps shown in FIG. 1, FIG. 3, FIG. 5, and FIG. 11 may include a plurality of sub-steps or stages. The sub-steps or stages are not necessarily executed at the same time, but may be executed at different times. The sub-steps or stages are not necessarily executed sequentially, but may be executed alternately with other steps or at least some of sub-steps or stages of other steps.

Those of ordinary skill in the art may understand that all or some of the procedures in the methods of the above embodiments may be implemented by a computer program instructing related hardware. The computer program may be stored in a non-volatile computer-readable storage medium. When the computer program is executed, the procedures in the embodiments of the above methods may be performed. Any reference to a memory, a storage, a database, or other media used in the embodiments of the present disclosure may include a non-volatile and/or volatile memory.

The present disclosure is described with reference to the flowcharts and/or block diagrams of the method, the apparatus (device), and the computer program product according to the embodiments of the present disclosure. It should be understood that computer program instructions may be used to implement each process and/or each block in the flowcharts and/or the block diagrams and a combination of a process and/or a block in the flowcharts and/or the block diagrams. These computer program instructions may be provided for a general-purpose computer, a dedicated computer, an embedded processor, or a processor of any other programmable data processing device to generate a machine, such that the instructions executed by a computer or a processor of any other programmable data processing device generate an apparatus for implementing a specific function in one or more processes in the flowcharts and/or in one or more blocks in the block diagrams.

These computer program instructions may also be stored in a computer readable memory that can instruct the computer or any other programmable data processing device to work in a specific manner, such that the instructions stored in the computer readable memory generate an artifact that includes an instruction apparatus. The instruction apparatus implements a specific function in one or more processes in the flowcharts and/or in one or more blocks in the block diagrams.

These computer program instructions may also be loaded onto a computer or another programmable data processing device, such that a series of operations and steps are performed on the computer or the another programmable device, thereby generating computer-implemented processing. Therefore, the instructions executed on the computer or the another programmable device provide steps for implementing a function specified in one or more processes in the flowcharts and/or in one or more blocks in the block diagrams.

It should be noted that the above embodiments are merely for the purpose of description instead of limiting the present disclosure.

The embodiments of this specification are described in a progressive manner, and each embodiment focuses on differences from other embodiments. The same or similar parts between the embodiments may refer to each other.

The technical features of the above embodiments can be employed in arbitrary combinations. To provide a concise description, all possible combinations of all technical features of the above embodiments may not be described; however, these combinations of technical features should be construed as disclosed in this specification as long as no contradiction occurs.

The above embodiments are only intended to illustrate several implementations of the present disclosure in detail, and they should not be construed as a limitation to the patentable scope of the present disclosure. It should be noted that those of ordinary skill in the art can further make variations and improvements without departing from the conception of the present disclosure. These variations and improvements all fall within the protection scope of the present disclosure. Therefore, the protection scope of the present disclosure should be subject to the protection scope defined by the claims.

1. A method of analyzing data, comprising:
obtaining a single shmoo plot of each pin of a memory particle; and
constructing an integrated shmoo plot of the memory particle based on the single shmoo plot of each of the pins, wherein each test point of the integrated shmoo plot is marked with a pass proportion, and the pass proportion is configured to represent a proportion of a quantity of passed single shmoo plots at a corresponding test point to a total quantity of the single shmoo plots.

2. The method of analyzing data according to claim 1, wherein the integrated shmoo plot comprises a feature region and a pass region that are partially overlapped, the pass region comprises a common pass region of the single shmoo plots, the pass proportion of the test point in the common pass region is 100%, and the pass proportion of the test point in the feature region is greater than 0 and less than 100%.

3. The method of analyzing data according to claim 2, wherein the feature region has at least two types of first identifiers for representing the pass proportion, and different first identifiers represent different pass proportions.

4. The method of analyzing data according to claim 3, wherein the first identifier comprises a digital identifier, the method further comprises determining a pin uniformity of the memory particle:
obtaining a difference between the digital identifiers of any two adjacent test points in the feature region; and when at least one of the differences obtained is greater than or equal to a preset difference threshold, determining that the pin uniformity of the memory particle is poor; otherwise, determining that the pin uniformity of the memory particle is good; or
obtaining a minimum value of the digital identifiers; and when the minimum value is greater than or equal to a preset standard threshold, determining that the pin uniformity of the memory particle is good; otherwise, determining that the pin uniformity of the memory particle is poor.

5. The method of analyzing data according to claim 2, wherein the test point in the feature region is further marked with a second identifier for representing a corresponding pin.

6. The method of analyzing data according to claim 2, further comprising determining whether the memory particle has an edge defect:
obtaining a standard pass region of the integrated shmoo plot of the memory particle;
determining, as a first coordinate axis, an axis of symmetry that is of the standard pass region and extends along a frequency scanning direction, and determining, as a second coordinate axis, an axis of symmetry that is of the standard pass region and extends along a voltage scanning direction or a straight line of a boundary line that is of the standard pass region and extends along the voltage scanning direction;
obtaining an intersection point of a boundary line of the feature region and the first coordinate axis, and obtaining a distance between the intersection point and a vertical point of coordinate axes, wherein the vertical point of coordinate axes is a vertical point of the first coordinate axis and the second coordinate axis; and
when the distance is greater than or equal to a preset distance threshold, determining that the memory particle has the edge defect.

7. The method of analyzing data according to claim 2, further comprising determining whether the memory particle has a void defect:
determining whether there is a failed region in the pass region, wherein the failed region contains a plurality of consecutive failed points;
when yes, determining whether any one of the failed regions comprises at least two consecutive failed points in a voltage scanning direction and at least two consecutive failed points in a frequency scanning direction; and
when yes, determining that the memory particle has the void defect.

8. The method of analyzing data according to claim 1, further comprising determining whether the memory particle has a voltage linearity defect:
determining whether there is a voltage linearity defect region in the integrated shmoo plot, wherein the voltage linearity defect region comprises at least one voltage failure line that extends along a frequency scanning direction and intersects with two opposite boundary lines of the integrated shmoo plot, and each test point on the voltage failure line is a failed point; and
when yes, determining that the memory particle has the voltage linearity defect.

9. The method of analyzing data according to claim 1, further comprising determining whether the memory particle has a frequency linearity defect:
determining whether there is a frequency linearity defect region in the integrated shmoo plot, wherein the frequency linearity defect region comprises at least one frequency failure line that extends along a voltage scanning direction and intersects with two opposite boundary lines of the integrated shmoo plot, and each test point on the frequency failure line is a failed point; and
when yes, determining that the memory particle has the frequency linearity defect.

10. A method of analyzing data, comprising:
obtaining a single shmoo plot of any one of a plurality of memory particles; and
constructing an integrated shmoo plot of a memory based on the single shmoo plots of the memory particles, wherein each test point of the integrated shmoo plot is marked with a third identifier, and the third identifier is configured to represent a code of a passed memory particle at a corresponding test point.

11. An apparatus of analyzing data, comprising a memory and a processor, wherein the memory stores a computer program, and the processor executes the computer program to implement:
obtaining a single shmoo plot of each pin of a memory particle; and
constructing an integrated shmoo plot of the memory particle based on the single shmoo plot of each of the pins, wherein each test point of the integrated shmoo plot is marked with a pass proportion, and the pass proportion is configured to represent a proportion of a quantity of passed single shmoo plots at a corresponding test point to a total quantity of the single shmoo plots.

12. The apparatus of analyzing data according to claim 11, wherein the integrated shmoo plot comprises a feature region and a pass region that are partially overlapped, the pass region comprises a common pass region of the single shmoo plots, the pass proportion of the test point in the common pass region is 100%, the pass proportion of the test point in the feature region is greater than 0 and less than 100%, the feature region has at least two types of first identifiers for representing the pass proportion, and different first identifiers represent different pass proportions.

13. The apparatus of analyzing data according to claim 12, wherein the first identifier comprises a digital identifier, the processor executes the computer program to further implement:
comparing the digital identifiers of two adjacent test points in the feature region, or obtaining a minimum value of the digital identifiers and comparing the minimum value with a preset standard threshold; and determining a pin uniformity of the memory particle based on a comparison result.

14. The apparatus of analyzing data according to claim 13, wherein the test point in the feature region is further marked with a second identifier for representing a corresponding pin.

15. The apparatus of analyzing data according to claim 11, wherein the processor executes the computer program to further implement:
obtaining a standard pass region of the integrated shmoo plot of the memory particle;
determining, as a first coordinate axis, an axis of symmetry that is of the standard pass region and extends along a frequency scanning direction, and determining, as a second coordinate axis, an axis of symmetry that is of the standard pass region and extends along a voltage scanning direction or a straight line of a boundary line that is of the standard pass region and extends along the voltage scanning direction; and
obtaining an intersection point of a boundary line of a feature region and the first coordinate axis, and obtaining a distance between the intersection point and a vertical point of coordinate axes, wherein the vertical point of coordinate axes is a vertical point of the first coordinate axis and the second coordinate axis; and when the distance is greater than or equal to a preset distance threshold, determining that the memory particle has an edge defect.

16. The apparatus of analyzing data according to claim 12, wherein the processor executes the computer program to further implement:
determining whether there is a failed region in the pass region, wherein the failed region contains a plurality of consecutive failed points; when yes, determining whether any one of the failed regions comprises at least two consecutive failed points in a voltage scanning direction and at least two consecutive failed points in a frequency scanning direction; and when yes, determining that the memory particle has a void defect.

17. The apparatus of analyzing data according to claim 12, wherein the processor executes the computer program to further implement:
determining whether there is a voltage linearity defect region in the integrated shmoo plot, wherein the voltage linearity defect region comprises at least one voltage failure line that extends along a frequency scanning direction and intersects with two opposite boundary lines of the integrated shmoo plot, and each test point on the voltage failure line is a failed point; and when yes, determining that the memory particle has a voltage linearity defect.

18. The apparatus of analyzing data according to claim 12, wherein the processor executes the computer program to further implement:
determining whether there is a frequency linearity defect region in the integrated shmoo plot, wherein the frequency linearity defect region comprises at least one frequency failure line that extends along a voltage scanning direction and intersects with two opposite boundary lines of the integrated shmoo plot, and each test point on the frequency failure line is a failed point; and when yes, determining that the memory particle has a frequency linearity defect.

19. A computer-readable storage medium, storing a computer program, wherein the computer program is executed by a processor to implement the method according to claim 1.
